(19) United States
(12) Patent Application Publication
(10) Pub. No.: US 2020/0388531 A1
(43) Pub. Date: Dec. 10, 2020

(54) ION IMPLANTATION ASSISTED CURING FOR FLOWABLE POROUS DIELECTRICS

(71) Applicant: International Business Machines Corporation, Armonk, NY (US)

(72) Inventors: Devika Sil, Rensselaer, NY (US); Matthew T. Shoudy, Guilderland, NY (US); Oleg Gluschenkov, Tannersville, NY (US); Benjamin D. Briggs, Waterford, NY (US); Danielle Durrant, Duanesburg, NY (US); Yasir Sulehria, Latham, NY (US)

(21) Appl. No.: 16/431,186

(22) Filed: Jun. 4, 2019

(51) Int. Cl. H01L 21/768

(52) U.S. Cl. CPC H01L 21/76825; H01L 21/76895

(57) ABSTRACT

Embodiments of the invention include a method of forming a multi-layer integrated circuit (IC) structure that includes a forming a first IC layer above the substrate, wherein the first IC layer includes a network of interconnect structures, wherein the network of interconnect structures is configured to communicatively couple electronic devices of the IC. A second IC layer is formed over the first IC layer. The second IC layer is implanted with a predetermined ion implantation dose, maintained at a predetermined temperature, and further exposed to electromagnetic radiation from an energy source. The second IC layer is configured to, based at least in part of being exposed to the ion implantation and the electromagnetic radiation, experience changes in the chemical composition of the second IC layer and transform the second IC layer.

### BACKGROUND

The present invention generally relates to fabrication methods and resulting structures for integrated circuit (IC) wafers. More specifically, the present invention relates to fabrication methodologies and resulting structures for performing ion implantation assisted curing of low-k flowable porous dielectric films of an IC wafer.

ICs are fabricated in a series of stages, including a front-end-of-line (FEOL) stage, a middle-of-line (MOL) stage and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts (e.g., CA) and other structures that communicatively couple to active regions (e.g., gate, source, and drain) of the device element. For example, the silicidation of source/drain regions, as well as the deposition of metal contacts, can occur during the MOL stage to connect the elements patterned during the FEOL stage. Layers of interconnections are formed above these logical and functional layers during the BEOL stage to complete the IC. Most ICs need more than one layer of wires to form all the necessary connections, and as many as 5-12 layers are added in the BEOL process. The various BEOL layers are interconnected by vias that couple from one layer to another.

Insulating dielectric materials are used throughout the layers of an IC to perform a variety of functions, including stabilizing the IC structure and providing electrical isolation of the IC elements. For example, the metal interconnecting wires in the BEOL region of the IC are isolated by dielectric layers to prevent the wires from creating a short circuit with other metal layers.

The insulating material in the BEOL layers of an IC is often cured during IC fabrication in order to achieve desired mechanical and chemical properties of the insulating material.

### SUMMARY

Embodiments of the present invention are directed to a method for fabricating a multi-layer integrated circuit (IC) structure. A non-limiting example of the method includes forming a forming a first IC layer above the substrate, wherein the first IC layer includes a network of interconnect structures including conductive material, wherein the network of interconnect structures is configured to communicatively couple electronic devices of the IC to one another and exhibit topography. A second IC layer is formed over the first IC layer, wherein the second IC layer is made up of flowable dielectric material, and wherein the second IC layer further includes a top surface and a bottom surface. The second IC layer is subjected to ion implantation with a predetermined ion implantation dose, and is further subjected to electromagnetic radiation from an energy source. The second IC layer is configured to, based at least in part of being exposed to the implanted ions and the electromagnetic radiation, experience changes in the chemical composition of the dielectric material and transform properties of the second IC layer.

Embodiments of the present invention are directed to a method for fabricating a multi-layer integrated circuit (IC) structure. A non-limiting example of the method includes forming a forming a first IC layer above the substrate, wherein the first IC layer includes a network of interconnect structures including conductive material, wherein the network of interconnect structures is configured to communicatively couple electronic devices of the IC to one another and exhibit topography. A second IC layer is formed over the first IC layer, wherein the second IC layer is made up of flowable dielectric material including a base level chemical backbone network strength. The second IC layer is subjected to ion implantation with a predetermined dose of ions followed by UV curing, wherein the temperature experienced by the second IC layer as a result of the UV curing is predetermined. The second IC layer is configured to, based at least in part of being exposed to the implanted ions and the UV radiation from the UV curing, experience changes in the level of chemical backbone network strength of the dielectric material, wherein the chemical backbone network strength after ion implantation and UV curing is higher than the chemical backbone network strength of the second IC layer cured by UV curing only.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts a portion of an IC wafer in accordance with aspects of the invention;

FIG. 2 depicts a portion of an IC wafer in accordance with aspects of the invention;

FIG. 3 depicts a portion of an IC wafer in accordance with aspects of the invention;

FIGS. 4-9 depict the results of fabrication operations for forming IC structures in accordance with aspect of the invention, in which:

FIG. 4 depicts a schematic illustration of an IC after fabrication operations according to embodiments of the invention;

FIG. 5 depicts a schematic illustration of an IC after fabrication operations according to embodiments of the invention;

FIG. 6 depicts a schematic illustration of an IC after fabrication operations according to embodiments of the invention; and

FIG. 7 depicts a schematic illustration of an IC after fabrication operations according to embodiments of the invention;

FIG. 8 depicts a schematic illustration of an IC after fabrication operations according to embodiments of the invention; and

FIG. 9 depicts a schematic illustration of an IC after fabrication operations according to embodiments of the invention;

FIG. 10 depicts experimental data according to the embodiments of the invention;

FIG. 11 depicts experimental data according to the embodiments of the invention;

FIG. 12 depicts experimental data according to the embodiments of the invention; and

FIG. 13 depicts experimental data according to the embodiments of the invention.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two- or three-digit reference numbers. With minor exceptions, the leftmost digit(s) of each reference number correspond to the figure in which its element is first illustrated.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the invention, semiconductor devices are used in a variety of electronic and electro-optical applications. ICs are typically formed from various circuit configurations of semiconductor devices (e.g., transistors, capacitors, resistors, etc.) and conductive interconnect layers (known as metallization layers) formed on semiconductor wafers. Alternatively, semiconductor devices can be formed as monolithic devices, e.g., discrete devices. Semiconductor devices and conductive interconnect layers are formed on semiconductor wafers by depositing many types of thin films of material over the semiconductor wafers, patterning the thin films, doping selective regions of the semiconductor wafers, etc.

In contemporary semiconductor fabrication processes, a large number of semiconductor devices and conductive interconnect layers are fabricated. More specifically, during the first portion of chip-making (i.e., the FEOL stage), the individual components (transistors, capacitors, etc.) are fabricated on the wafer. The MOL stage follows the FEOL stage and typically includes process flows for forming the contacts and other structures that communicatively couple to active regions (e.g., gate, source, and drain) of the device element. For example, the silicidation of source/drain regions, as well as the deposition of metal contacts, can occur during the MOL stage to connect the individual components fabricated during the FEOL stage. In the BEOL stage, these components are connected to each other to distribute signals, as well as power and ground. The conductive interconnect layers serve as a network of pathways that transport signals throughout an IC, thereby connecting circuit components of the IC into a functioning whole and to the outside world. Because there typically isn't enough room on the chip surface to create all of the necessary connections in a single layer, chip manufacturers build vertical levels of interconnects. While simpler ICs can have just a few metal layers, complex ICs can have ten or more layers of wiring.

Interconnect structures close to the transistors need to be small because they attach/join to the components that are themselves very small and often closely packed together. These lower-level lines, which can be referred to as local interconnects, are usually thin and short in length. Global interconnects are higher up in the structure and travel between different blocks of the circuit. Thus, global interconnects are typically thick, long, and widely separated. Connections between interconnect levels, called vias, allow signals and power to be transmitted from one layer to the next. For example, a through-silicon via (TSV) is a conductive contact that passes completely through a given semiconductor wafer or die. In multilevel IC configurations, for example, a TSV can be used to form vertical interconnections between a semiconductor device located on one level of the IC and an interconnect layer located on another level of the IC. These vertical interconnect structures include an appropriate metal and provide the electrical connection of the various stacked metallization layers.

Interconnect structures are often formed in a stack. For example, a transistor can have a gate contact (also referred to as a CB contact) and S/D contacts (also referred to as CA contacts). The S/D contacts can extend through an interlayer dielectric (ILD) region of the IC from a metal wire or via in the BEOL metal level to metal plugs (also referred to as trench silicide (TS) contacts), which are on the S/D regions of the transistor. A conventional interconnect stack fabrication process starts with the deposition of an ILD insulating material (e.g., SiO₂) over the transistor followed by the creation of trenches in the ILD insulating material. The trenches are positioned over the portion of the transistor (source, gate, drain) to which electrical coupling will be made. The liner/barrier material is deposited within the trench, and, for S/D regions, the remaining trench volume is filled with material that will form the metal plugs (or TS contacts) using, for example, a chemical/electroplating process. The excess metal is removed to form a flat surface for subsequent processing. A cap layer can be deposited over the exposed top surface of the metal plug. This process is repeated until all portions of the interconnect structure stack have been formed.

The above-described conductive lines (i.e., metal wires and vias) in BEOL layers of a multi-level IC structures can be formed using, for example, a dual damascene process that includes depositing a dielectric material as a blanket film, lithographically patterning the dielectric material, and applying a reactive ion etched (RIE), creating both trenches and vias. The pattern is then coated by a refractory metal barrier such as Ta and TaNₓ followed by a thin sputtered metal (e.g., copper) seed layer. The seed layer allows for the electrochemical deposition (ECD) of a thick metal layer that fills up the holes. Excessive metal is removed, and the surface is planarized by chemical mechanical polishing (CMP). A thin dielectric film also known as a “cap” is deposited over the patterned copper lines. This dual damascene process is repeated at each of the higher levels built.

As predicted by Moore's law, semiconductor devices continue to scale down in order to improve device performance and place more transistors on the substrate. As the number of devices and circuits on a semiconductor chip increases, the BEOL interconnect wiring density and the number of metal levels also increase. The corresponding scaling of interconnect wiring structures causes an increase in the parasitic resistance (R) and capacitance (C) associated with the interconnects. The RC product is a measure of the time delay introduced into the circuitry by the BEOL structures. In order to provide a parasitic RC level that is sufficiently low to support high signal speed applications, regions of the BEOL dielectric material are formed from low-k dielectric materials having a dielectric constant of less than silicon dioxide, and the interconnect structures (e.g., wire lines and vias) can be formed from copper-containing material. Dielectric materials like fluorine-doped silicon dioxide, porous organosilicate glass material (e.g., SiCOH), porous silicon dioxide, organic polymeric materials like polyimide, polynorbornenes, benzocyclobutene, hydrogen sisesquioxane can be used as suitable BEOL dielectrics for reducing interconnect capacitance.

However, there are practical difficulties in integrating low-k dielectric materials into the IC structure at the BEOL stage. First, both the physical as well as the chemical properties of many of these low-k materials are not optimum for the subtractive processes such reactive ion etching (RIE), chemical mechanical polishing (CMP), and wet etching. For example, the materials used as low-k BEOL dielectrics are too soft and erode during CMP. These materials are also susceptible to plasma induced damage during via etch, an increased wet etch rate of the damaged layer, and blown-out via profiles. Most of the low-k dielectric materials are known to degrade under thermal excursions to temperature at or above 400° C. Hence, the device interconnection processes are limited to 400° C. and lower temperatures. Another example of a low-k BEOL dielectric is a porous inorganic dielectric material such as aerogels. They are known to be mechanically weak and friable, making them susceptible to damage. The impact of a damaged BEOL dielectric layer becomes especially acute for smaller IC geometries. For a 7 nm node, a 2.5× increase in the thickness of a damaged ILD layer can result in a capacitance penalty of 6% negating most of the previously described benefits of having a low-k BEOL dielectric.

A suitable BEOL dielectric for reducing interconnect capacitance is a porous organosilicate glass material (e.g., SiCOH) having a dielectric constant k down to around 2.5. In general, in order to reduce the dielectric constant k, BEOL dielectric contains nanopores in its siloxane backbone network. This can be accomplished by depositing BEOL dielectric material containing in a chemical vapor deposition (CVD) reactor using organosilicon precursors and forming nanopores and crosslinking siloxane groups using ultraviolet (UV) curing processes. The CVD process mixes the organic precursor for sacrificial porogen (e.g., cyclohexene, and the like) and the matrix precursor for the low-k backbone structure (e.g., decamethylcyclopentasiloxane, diethoxymethylsilane, dimethyldimethoxysilane, tetramethylcyclotetrasilane, octamethylcyclotetrasilane, and the like). The CVD process can be enhanced by gaseous discharge or plasma (plasma enhanced CVD or PECVD). The substrate temperature during an exemplary UV curing process is limited to 400° C., the damage threshold for the formed temperature-sensitive structures in an IC. This results in efficient crosslinking and forming a strong backbone network in the BEOL dielectric, a benefit obtained from photochemical reactions initiated by abundant energetic UV photons. Thus, UV curing can be applied to BEOL dielectric materials to lower k.

In an IC structure, geometrical scaling of interconnect features also leads to reduced spacing between adjacent vias and wires. This reduced spacing and in turn results in weak electrical isolation of materials within the interconnect leading to a severe degradation in interconnect Time Dependent Dielectric Breakdown or TDDB. TDDB is a measure of how long an integrated circuit will last at a given operating supply voltage. Often the overall interconnect TDDB metric is referred to as via TDDB to emphasize the loss of control of via-to-adjacent-wire spacing. This problem is especially acute for scaled-down, high-performance integrated circuits operated at a relatively elevated power supply voltage of about 1 Volt, whereas typical IC's operate at a lower power supply voltage of 0.6-0.9V. Numerous self-aligned integration schemes are proposed to regain control of via-to-adjacent-wire spacing. One such scheme is known as Fully Aligned Via or FAV. It relies on first creating topography in the underlying interconnect layer by partially recessing the conductive interconnect structure and disposing a thin and conformal dielectric etch stop layer over the recessed structure. In the following step, a next-level BEOL dielectric is deposited over a surface with designed topography features. Further, vias are etched in the next-level BEOL dielectric layer. The via profiles are controlled by the material properties of the next-level BEOL dielectric as well as by the dielectric etch stop layer in the region below. Although the presence of the dielectric etch-stop layer allows for regaining control of the via-to-adjacent-wire spacing in the lower region, the etch resistance of BEOL dielectric still plays a major role in controlling this spacing in the upper region. Importantly, the BEOL dielectric is required be deposited over a surface with designed topography features and, hence, must possess a gap fill capability.

The gap fill capability for BEOL low-k dielectrics is not unique to the FAV integration scheme. There are other instances where a low-k dielectric is used to encapsulate and electrically isolate features with topography. Conductive memory cell elements, 3 dimensional capacitors, and other useful devices have topographical features that can require the use of low-k BEOL dielectric with a gap fill capability. A class of low-k dielectrics known as flowable or spin-on low-k dielectrics have an inherent gap fill capability. Compared to more conventional BEOL dielectrics, these materials contain a larger organic component to allow for their flowability and to assist in their ability to fill topographic features. In addition, these dielectrics contain the similar ingredients as their PECVD counterparts, namely, the matrix precursor for the low-k backbone structure such as octamethylcyclotetrasilane and tetramethoxysilane. As-deposited, such flowable or spin-on materials have a dielectric constant of above about 3.5. These flowable or spin-on materials require a cure process to reduce their large organic component, lower their dielectric constant, and form a chemical backbone network. A conventional UV cure process at about 385° C. is typically used for this purpose. The resultant low-k material has k of about 2.8, the porosity level of about 10%. The wet etch rate for plasma damaged flowable or spin-on film is 5-6 times faster compared to a conventional low-k film with similar k. This higher wet etch rate of plasma damaged flowable or spin-on material makes the vias etched in such flowable low-k film susceptible to unpredictable profile geometries negating most of the benefits afforded by the FAV integration scheme.

Turning now to an overview of the aspects of the invention, embodiments of the invention address the problems associated with using low-k flowable or spin-on bulk ILD by providing a novel curing process for flowable or spin-on low-k BEOL dielectrics. In aspects of the invention, a novel curing technique is applied to a semiconductor structure having a second IC layer formed over a first IC layer, wherein the first IC layer can include conductive interconnect structures (e.g., wires and vias) formed therein and the surface of the first layer can have a topography. In accordance with aspects of the invention, an ion implantation is conducted on to the second IC layer prior to its curing. In accordance with aspects of the invention, an energy source in the form of electromagnetic radiation also directed into the implanted second IC layer while keeping the implanted second IC layer at an elevated temperature. Accordingly, the exposure to the electromagnetic radiation and an elevated temperature transforms the second implanted IC layer. In accordance with aspects of the invention, the ion implantation step implants light ions with their atomic number Z equal to or less than that of Argon (Z=18) into the deposited dielectric layer of the second IC layer. The implanted ions can include ionized elements or molecules like He, B, C, N, H, and H₂. In accordance with aspects of the invention, the energy of the individual ions determines the depth of penetration into the second IC layer. Varying penetration levels can be achieved by predetermining the ion implantation energy. Multiple implantation energies are employed to distribute the ions uniformly throughout the film. According to the aspects of the invention, the ion penetration depths are selected to uniformly distribute ions throughout the entire dielectric film or a given top portion of the dielectric film. In accordance with aspects of the invention, the ion implantation dose is selected such that implanted elements do not exceed 0.5 atomic percent of dielectric material constituents.

In accordance with aspects of the invention, the implanted dielectric film is cured with the aid of an energy source in the form of electromagnetic radiation. During this curing process the film is maintained at an elevated temperature. The wavelength of electromagnetic radiation is selected to enable a chemical transformation in the implanted dielectric film. According to the aspects of the invention, the electromagnetic radiation wavelength is in the UV region of spectrum and is preferably shorter than 250 nm. According to the aspects of the invention, the elevated film temperature can be equal or higher than the substrate temperature and its selection depends on the duration of electromagnetic radiation exposure. For exposures longer than several seconds, the film temperature is limited to 400° C.; for exposures shorter than tens of milliseconds but longer than several microseconds the film temperature is limited to 800° C.; and for exposures shorter than several microseconds, the film temperature is limited to 1200° C.

In accordance with aspects of the invention, the second IC layer is first implanted with low-dose light ions followed by an exposure to an energy source. The novel combination of the low-dose implantation followed by chemical transformation induced by the energy source transforms the second IC layer into a new and improved material.

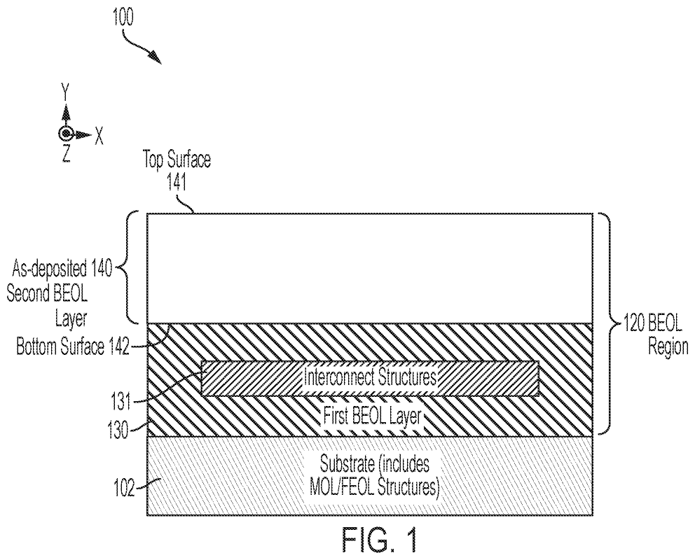

Turning now to a more detailed description of aspects of the present invention, FIG. 1 depicts a portion of an IC wafer 100 in accordance with aspects of the invention. The IC wafer 100 includes a substrate (having middle-of-line (MOL) and front-end-of-line (FEOL) structures) 102 and a BEOL region 120 formed over the substrate 102. The BEOL region 120 includes a first BEOL dielectric layer 130 and a second BEOL dielectric layer 140, configured and arranged as shown. The second BEOL dielectric layer 140 typically has a thickness of about 40 nm to about 150 nm. Commonly, the thickness of about 70 nm to 100 nm being more typical. In accordance with aspects of the invention, the interconnect structures 131 can be implemented as a network of conductive interconnect structures (e.g., wires and/or vias) configured to communicatively couple semiconductor devices (i.e., MOL/FEOL structures) of the substrate 102 to one another. Topographic features can be formed by the interconnect structures 131. Accordingly, the top surface of the first dielectric layer 130 or, equivalently, the bottom surface 142 of the second BEOL dielectric layer 140 can also include topographic features. In aspects of the invention, the first BEOL 130 can represent an MOL layer and the interconnect structures 131 can represent the MOL conductive elements and networks and the second BEOL layer 140 can represent the first BEOL layer formed on top of MOL layer 130.

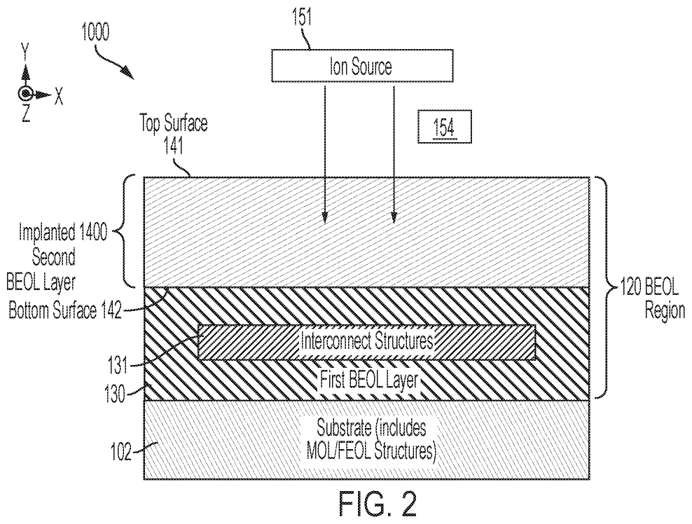

Referring now to FIG. 1-2, in accordance with aspects of the invention, the second BEOL dielectric film 140 is implanted with light ions 154. The ion source 151 can be a conventional beamline implanter that allows for selecting ions based on their mass, their implantation energy, and their implantation dose. The ion source 151 can be a plasma implanter that controls ion implantation energy through substrate bias and ambient gaseous chamber pressure and allows for selecting ion implantation dose. Selecting ion type in plasma implantation ions source 151 is done via selecting a proper feed gas to the gaseous plasma. For instance, He+ or H+/H₂+ plasma implantation would use He or H₂ feed gas, respectively. The implantation process results in breaking and distorting chemical bonding within the dielectric film 140 converting it into the dielectric film 1400. According to the aspects of the invention, light ions with an atomic number Z of equal to or less than that of Argon (Z=18) are preferred. Ions of He, B, C, N, H, and H₂ are preferred. Ions of He, H, and H₂ are highly preferred due to their chemical neutrality and ultra-low mass. According to the aspects of the invention, the ion implantation energies are selected to uniformly distribute ions and/or ion-induced damage throughout the entire dielectric film or a given top portion of the dielectric film. Ion implantation energy of from 1 keV to 30 keV are preferred. The exact implantation energy or the use of multiple energies depends on the ion mass or element atomic number and chemical constituents of the film 140. According to the aspects of the invention, the ion implantation dose is selected to break or distort enough chemical bonds in the film 140 without changing the chemical makeup of films 140 and 130 and structures 131. Accordingly, the ion implantation dose is selected such that the implanted elements do not exceed 0.5 atomic percent of chemical constituents of film 140. Ion implantation dose of from 10¹³ ions/cm² to 5×10¹⁴ ions/cm² are preferred. The exact implantation dose depends on the ion mass or atomic number and the depth of the implant. Ultra-light ions such as H+, H₂+, He+ tend to require a slightly higher implantation doses of from about 5×10¹³ ions/cm² to 5×10¹⁴ ions/cm² whereas more heavy ions such as N+, B+, C+ tend to require a slightly lower implantation dose of from about 10¹³ ions/cm² to 10¹⁴ ions/cm². This is due to the fact that the heavier ions distort or break more chemical bonds per each implanted ion. Importantly, the ion implantation tail dose potentially can penetrate into the lower regions of the IC structure, the low implantation dose ensures that the chemical makeup of underlying structures such as film 130 and interconnect 131 remains unaltered. Further, the low implantation dose also ensures that the implantation tail dose does not substantially damage the underlying structures.

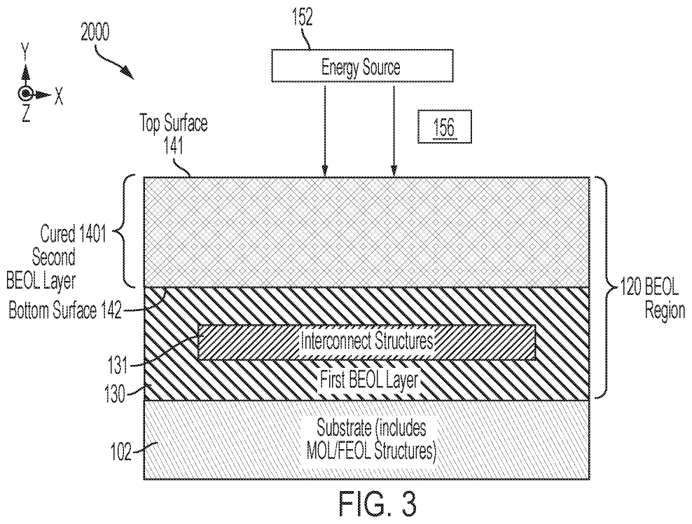

Referring now to FIG. 2-3, in accordance with aspects of the invention, the energy source 152 generates electromagnetic radiation 156 and directs it to the implanted film 1400 and the substrate 102. The film 1400 and substrate 102 temperatures are kept elevated during exposure to the radiation 156. The wavelength of electromagnetic radiation is selected to enable a chemical transformation in the implanted dielectric film 1400. According to the aspects of the invention, the electromagnetic radiation wavelength is in the UV region of spectrum and is preferably shorter than 250 nm. According to the aspects of the invention, the elevated film 1400 temperature can be equal or higher than the substrate 102 temperature and its selection depends on the duration of electromagnetic radiation exposure. For exposures longer than several seconds, the film temperature is limited to 400° C.; for exposures shorter than tens of milliseconds but longer than several microseconds the film temperature is limited to 800° C.; and for exposures shorter than several microseconds, the film temperature is limited to 1200° C. According to the aspects of the invention, this step is a conventional UV cure process wherein the energy source 152 is a UV cure lamp, the electromagnetic radiation 156 is UV lamp radiation with a wavelength of 150 nm to 250 nm. The temperatures of the film 1400 and substrate 102 are equal and in the range between 200° C. to 400° C., and the duration of this step is several minutes. Electromagnetic radiation 156 passing through film 1400 and the elevated temperature of the film 1400 chemically transforms the film 1400 into film 1401. Upon this transformation, the cured second BEOL film 1401 possesses unique material properties such that its dielectric constant is below 3 and typically within 2.7-2.9 range and its wet etch rate of plasma-ion-damaged material is 3-4 times improved (lower) than that of a flowable low-k film cured by conventional UV cure.

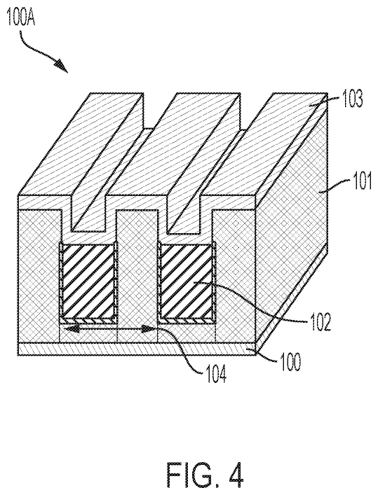

FIGS. 4-9 depict the results of fabrication operations for forming IC structures 100A, 100B, 100C, 100D, 100E and 100F in accordance with aspect of the invention. In FIG. 4, known fabrication operations have been used to form the multi-layered IC wafer 100A. A variety of well-known fabrication operations are suitable for forming the multi-layered IC wafer 100A to the fabrication stage shown in FIG. 4. Accordingly, in the interest of brevity, such well-known fabrication operations are either omitted or described and illustrated at a high level. As shown in FIG. 4, known fabrication operations have been used to form a substrate 100 having MOL & FEOL structures formed therein or thereon. Fabrication operations such as wafer preparation, isolation, and gate patterning have been used to form the FEOL structures, which can include structures such as wells, S/D regions, extension junctions, silicide regions, liners, and the like. The MOL structures include contacts and other structures that couple to the active regions (e.g., gate/source/drain) of the FEOL structures.

Referring still to FIG. 4, BEOL interconnect structures (i.e., metallization levels) 102 can be formed using a dual damascene process in which openings/trenches are etched in a dielectric layer (e.g., ILD 101) and filled with metal to create metallization levels (e.g., interconnect elements) of the BEOL interconnect structures 102. More specifically, FIG. 4 shows intermediate structure of the fully aligned via (FAV) BEOL integration sequence where known fabrication operations have been used to first partially recess the BEOL interconnect structures 102 creating surface topography and then form a conformal dielectric etch stop layer 103 over the partially-recessed metallization layer 102 in a low-k ILD layer/region 101 as part of the BEOL FAV structures formed during initial portions of the BEOL fabrication stage. The interconnect structures 102 can vary in dimensions depending upon the specification and requirement of the IC 100A. In aspects of the invention, the surface of intermediate structure 100A has a topography. In aspects of the invention, the interconnect structures 102 can be a conductive metal such as copper, cobalt, and the like. In aspects of the invention, the ILD region 101 can be formed from a low-k dielectric (e.g., k less than about 4), an ultra-low-k (ULK) dielectric (e.g., k less than about 2.5), and the like. In aspects of the invention, the intermediate structure 100A can also be represented by a MOL layer.

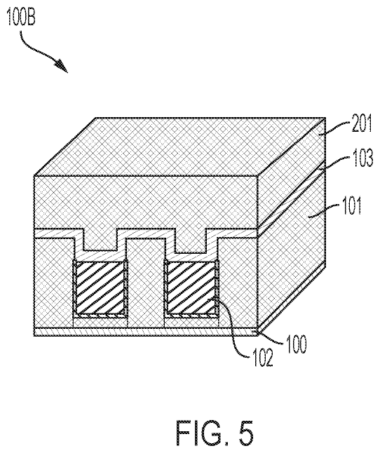

Referring to FIG. 5, to create a multi-level IC structure additional BEOL layers are required. This process initiates with the deposition of another dielectric film 201 followed by routine fabrication operations to build vertical metallization levels. In aspects of the invention, the dielectric film 201 is deposited over the surface 103 that has a topography. The deposited dielectric film 201 has a higher dielectric constant of higher than about 3.5 and needs to be cured to reduce the dielectric constant to below 3.

A novel curing process in accordance with the aspects of the invention can be implemented as depicted in FIGS. 5-9.

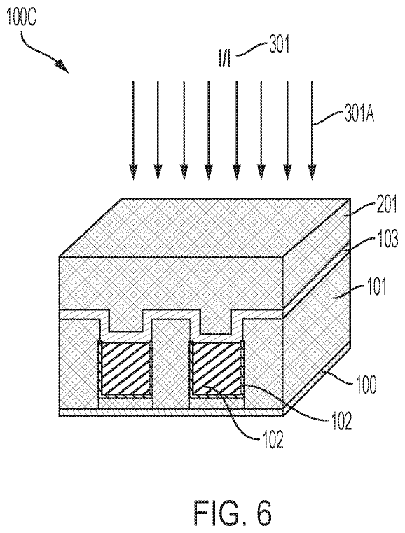

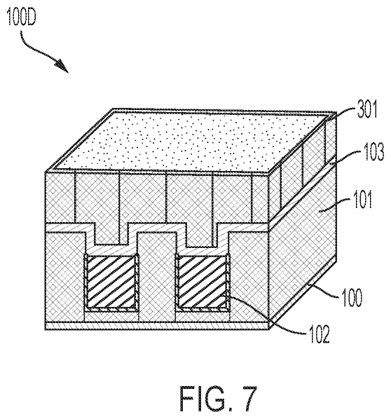

Referring to FIG. 6, the ion implantation process includes an ion source 301. In aspects of the invention, the ion source 301 can be either a beamline implanter or a plasma implanter. The flux of ions 301A of designed energy or energies are directed toward film 201 and substrate 102. Implanted ions break or distort the chemical bonding in material 201 without altering its chemical makeup. Light ions such as He+, B+, C+, N+, H+, and H₂+ are preferred. Ultra-light neutral ions such as He+, H+, and H₂+ are highly preferred. Accordingly, the ion implantation dose is selected such that the implanted dose does not exceed 0.5 atomic percent of chemical constituents of dielectric film 201. Ion implantation dose of 10¹³ ions/cm² to 5×10¹⁴ ions/cm² is preferred. According to the aspects of the invention, the ion implantation energies are selected to uniformly distribute ions and/or ion-induced damage throughout the entire dielectric film or a given top portion of the dielectric film. Ion implantation energy from 1 keV to 30 keV is preferred. Importantly, the ion implantation process does not result in the alteration of the chemical makeup of the underlying structures such as 101, 103 and 102 where the implant tail can penetrate. Further, the implant implantation tail dose not substantially damage underlying structures due to the selected low implantation dose. According to embodiments of the invention and referring to FIG. 6-7, an implanted low-k dielectric film is formed after ion implantation process while the underlying structures 101, 102, and 103 are not substantially altered.

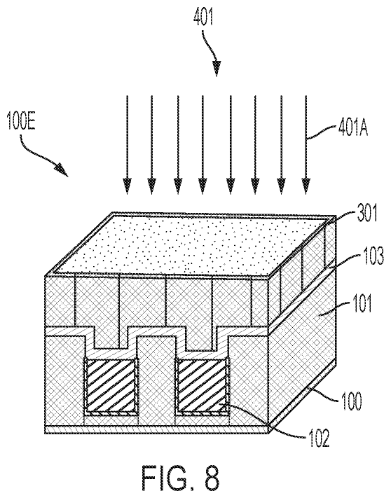

Referring to FIG. 8, the novel curing process further includes subjecting the implanted dielectric film 301 to an energy source 401. In accordance with aspects of the invention, the energy source 401 generates electromagnetic radiation 401A and directs it to implanted film 301 and the substrate 100. According to the aspects of the invention, the energy source 401 is a UV cure lamp and the electromagnetic radiation 401A are UV rays in the 150-250 nm wavelength band. During exposure to UV rays 401A, the implanted film 301 and the substrate 102 are kept at an elevated temperature from 200° C. to 400° C. The exposure to radiation 401A lasts for several minutes. Electromagnetic radiation 401A passing through the implanted film 301 along with elevated temperature of the dielectric film 301 results in the chemical transformation the film 301 into a cured low-k dielectric film 501.

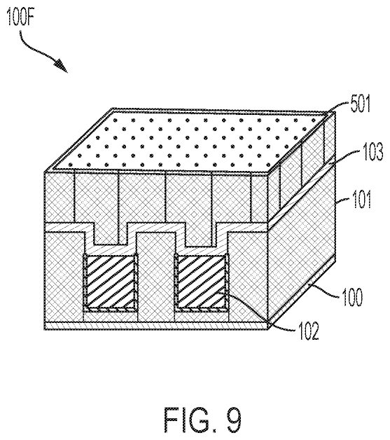

A robust curing process in accordance with the aspects of the invention can be implemented as depicted in FIG. 9. According to the embodiments of the invention, the low-k dielectric film 501 exhibits enhanced material properties such that its dielectric constant is below 3 and typically within 2.7-2.9 range and its wet etch rate of plasma-ion-damaged material is 3-4 times improved (lower) than that of a flowable low-k film cured by conventional UV cure.

The following examples illustrate aspects of the present invention but are not intended to limit the scope of the invention. The examples of aspects of the instant invention demonstrate that inventive process results in the formation of a hardened low-k dielectric film that is more etch resistant than a film cured by prior art methods.

Flowable SiCOH (FCVD SiCOH) film with as-deposited k of ˜4 and final “cured” k of ˜2.9-2.7 is typically used for BEOL ILD's with a gap fill capability. The flowable film properties are compared to PECVD porous SiCOH film with final “cured” k of ˜2.55-2.6 and a PECVD SiCOH film with k of ˜2.77-2.85. Porous PECVD “SiCOH 2.55” and FCVD SiCOH films were UV cured at 385° C. for several minutes to reduce their dielectric constant and to form a strong chemical backbone network. Low-porosity “SiCOH 2.7” film does not require any additional UV cure and its dielectric constant k is low enough right after deposition.

The key blanket properties of the common BEOL ILD films are displayed in Table I. FCVD SiCOH is more porous than the “SiCOH 2.7” film with comparable k and has the worst PID resistance (normalized wet etch rate of plasma-ion-damaged layer, lower is better) along with the lowest C content. PID resistance and the k value were measured for “SiCOH 2.55” and the FCVD SiCOH films post UV cure process.

TABLE I
Blanket property of common BEOL
ILDs with common curing steps.

| | SiCOH | | |
|---|---|---|---|
| Blanket | 2.7 | | |
| property | (Industry | SiCOH | FCVD |
| measured | standard) | 2.55 | SiCOH |
| k @ 150 C. | 2.77-2.85 | 2.55-2.6 | 2.78-2.8 |
| Bulk | | | |
| Porosity by | 6.5 | 18 | 11 |
| EP (%) | | | |
| PID | 0.13 | 0.17 | 0.75 |
| Atomic % C | 32 | 28 | 17-19 |

Novel ion implantation step was performed on flowable SiCOH (FCVD SiCOH) film with as-deposited k of ˜4 and final “cured” k of ˜2.78-2.9. Nitrogen and carbon implants were conducted in a conventional beamline implanter. Ion implantation targeted an implantation depth of approximately 40 nm for blanket films. N¹⁴+ and C¹²+ implantation energy was 8 keV. The implantation doses were selected to yield the concentration of implanted species in the range of from 1 to 0.05 at. %. The implanted flowable SiCOH films were subjected to a conventional UV cure process. The blanket dielectric parameters were measured on ILD films on Si substrates. Porosity was extracted using ellipsometry porosimetry. The PID wet etch resistance (normalized wet etch rate of plasma-ion-damaged layer, lower is better) was evaluated using the delta thickness method.

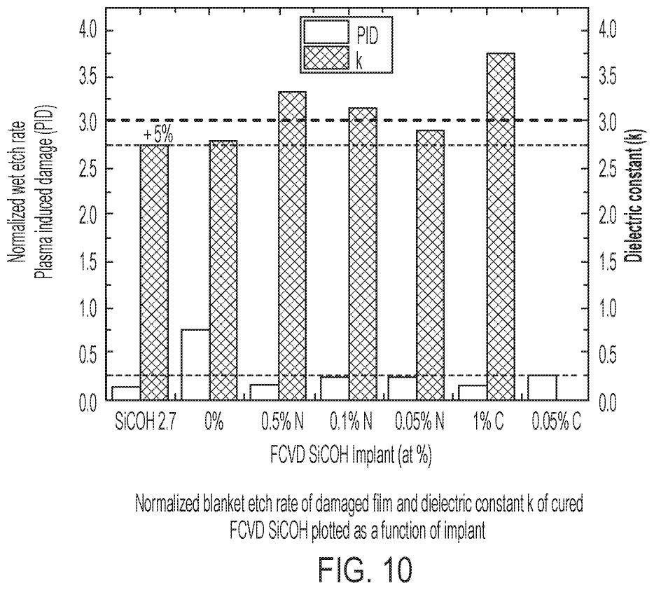

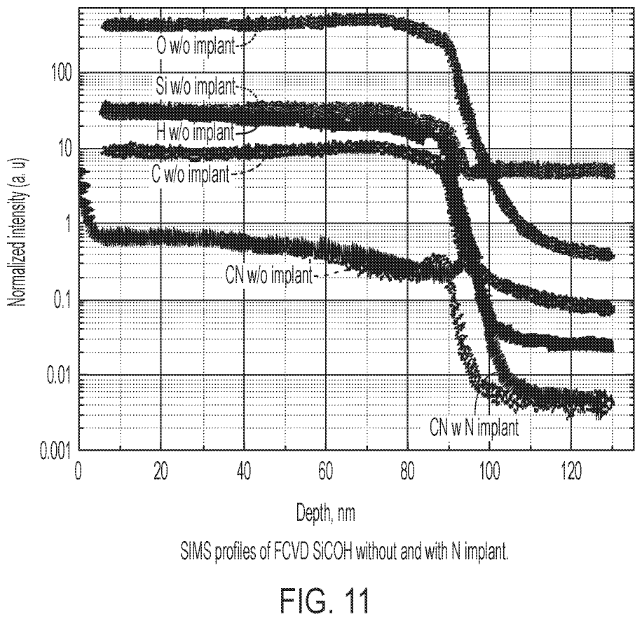

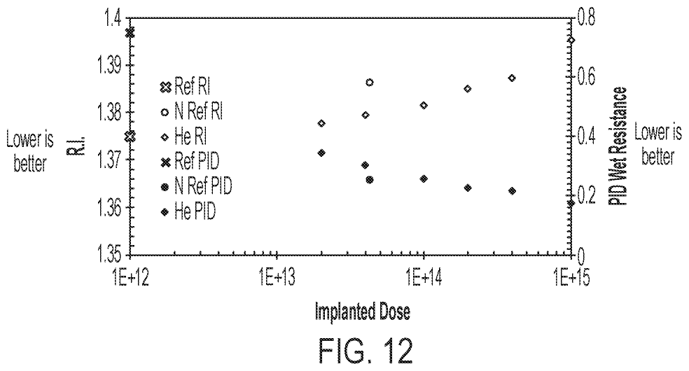

Ion implantation did not substantially alter the bulk carbon or nitrogen content of the cured films due to a low implanted dose. FIG. 10 shows the PID resistance (normalized wet etch rate of plasma-ion-damaged layer, lower is better) and corresponding k of implanted and cured FCVD SiCOH films as a function of implanted dose. A remarkable strengthening effect with little k impact is observed at the lowest implanted dose corresponding to the concentration of implanted nitrogen or carbon of about 0.05 at. % or, equivalently, ˜2×10¹⁹ implanted atoms/cm³. The implantation dose for C or N was ˜5×10¹³ ions/cm². At this low implanted dose and corresponding low volume concentration of an implanted element, no detectable change in nitrogen concentration was observed in the SIMS profiles due to the residual nitrogen present in the FCVD SiCOH films (FIG. 11). It also shows a rapid increase in k with rising implantation dose. This behavior suggests that the ion implantation toughening is not related to nitrogen or carbon chemical bonding but rather is due to the localized implantation-induced bond scission that leads to better crosslinking between freed-up siloxane groups in the post implantation UV curing process. The bond scission rate has an optimum point towards a low implanted dose range such that an excessive bond scission leads to a rapid increase in cured film k. To further test this point, chemically-neutral, ultra-light He ions were used to accomplish the flowable low-k material transformation similar to that induced by low-dose carbon or nitrogen implantations. The He implantation was conducted in the plasma implanter with the substrate bias of 2 keV. The He implanted flowable SiCOH films were subjected to a conventional UV cure process same as for nitrogen- or carbon-implanted films. The refractive index (R.I.) was measured to assess an increase in dielectric constant: a higher refractive index corresponds to a higher dielectric constant. FIG. 12 shows the results of nitrogen versus He implantation comparison. Both refractive index R.I. and PID resistance (normalized wet etch rate of plasma-ion-damaged layer, lower is better) are plotted versus the implanted dose. The He implantation dose of from 5×10¹³ ions/cm² to about 5×10¹⁴ ions/cm² matches or exceeds material properties of cured low-k films obtained with the aid of ˜5×10¹³ ions/cm² nitrogen implant.

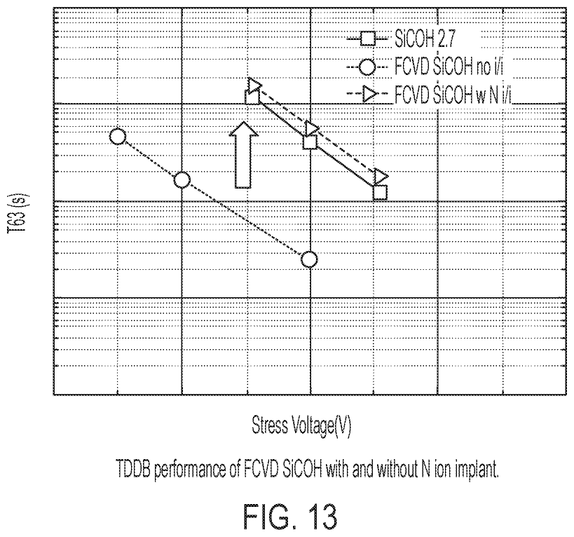

FCVD SiCOH films cured with the assistance of low-dose, light-ion implantation were integrated in our 7 nm BEOL test vehicle and via TDDB were measured on integrated structures. The via TDDB test measures electrical breakdown failure rates for numerous via-to-wire structures, representing the failure rates as Weibull failure distribution, and outputting lifetime at the 63rd percentile of Weibull distribution commonly known as the T63 lifetime. Improved via profiles consistent with the blanket PID resistance (normalized wet etch rate of plasma-ion-damaged layer, lower is better), contributed to a dramatic improvement in TDDB. The FCVD SiCOH film cured with the assistance of low-dose, light-ion implantation showed a nearly ˜20× improvement in T63 lifetime matching or exceeding that of “SiCOH 2.7” ILD (FIG. 13). In this case, the net gain in ILD strength exceeds any minute degradation in porosity and k resulting in a fundamental advantage within robustness-performance tradeoff.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the invention, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

1. A method of forming a multi-layer integrated circuit (IC) structure, the method comprising:
forming a substrate;
forming a first IC layer above the substrate, wherein the first IC layer comprises a network of interconnect structures embedded within a dielectric material, wherein the interconnect structures have a topography and are configured to communicatively couple electronic devices of the IC;
forming a second IC layer comprising a top surface and a bottom surface, wherein the second IC layer is above the first IC layer and comprises a flowable dielectric material;
using an ion source to implant the second IC layer with a predetermined dose of charged ions at a predetermined implantation energy; and
using an energy source to generate electromagnetic energy and expose the second IC layer to the electromagnetic energy;
wherein a temperature of the second IC layer is at a predetermined temperature;
wherein the predetermined temperature is equal or higher than the substrate temperature and the selection of the predetermined temperature depends on the duration of exposure to the electromagnetic energy;
wherein the electromagnetic radiation generated by the energy source passes through the top surface of the second IC layer; and
wherein the second IC layer is configured to, based at least in part of being implanted with the charged ions and exposed to the electromagnetic radiation, experience changes in the chemical composition of the dielectric material and transform properties of the second IC layer.

2. The method of claim 1, wherein the ion source is configured to implant charged ions of elements selected from a group consisting of He, N, C, B and molecular H₂.

3. The method of claim 2, wherein the ion source is configured to implant charged ions with an implantation energy between about 1 keV to about 30 keV.

4. The method of claim 1, wherein the implantation dose is between 10¹³ ion/cm² to 5×10¹⁴ ions/cm².

5. The method of claim 1, wherein the predetermined dose of charged ions is selected such that the concentration of implanted charged ions in the second IC layer is less than or equal to about 0.5 atomic % of the flowable dielectric material composition.

6. The method of claim 1, wherein:
the predetermined temperature is less than or equal to about 400° C.

7. The method of claim 1, wherein the predetermined temperature of second IC layer changes based at least in part on the duration of exposure of the second IC layer to the electromagnetic radiation.

8. The method of claim 1, wherein the second IC layer is implanted with the charged ions prior to being exposed to the electromagnetic energy.

9. The method of claim 1, wherein flowable dielectric of the second IC layer comprises gap fill properties with a predetermined chemical backbone network strength.

10. A method of forming a multi-layer integrated circuit (IC) structure, the method comprising:
forming a substrate;
forming a first IC layer above the substrate, wherein the first IC layer comprises a network of interconnect structures embedded within a dielectric material, wherein the interconnect structures have a topography and are configured to communicatively couple electronic devices of the IC;
forming a second IC layer comprising a top surface and a bottom surface, wherein the second IC layer is above the first IC layer and comprises a flowable dielectric material comprising a first chemical backbone network strength; and
subjecting the second IC layer to a predetermined dose ion implantation followed by UV curing;
wherein the predetermined dose has no effect on the underlying layers or structures within the multi-layered IC structure;
wherein a predetermined temperature is created in the second IC layer for the UV curing;
wherein the predetermined temperature is equal or higher than the substrate temperature and the selection of the predetermined temperature depends on the duration of exposure to the electromagnetic energy;
wherein the second IC layer is configured to, based at least in part of being subjected to the predetermined dose ion implantation and UV curing, experience changes in the first chemical backbone network strength of the flowable dielectric material of the second IC layer such that the second IC layer has a second chemical backbone network strength; and
wherein the second chemical backbone network strength is higher than the first chemical backbone network strength of the flowable dielectric material of the second IC layer.

11. The method of claim 10, wherein the ion source is configured to implant charged ions of elements selected from a group consisting of He, N, C, B and molecular H₂.

12. The method of claim 10, wherein the ion source is configured to implant charged ions with the implantation energy between 1 keV to 30 keV.

13. The method of claim 10, wherein the ion source is configured to implant charged ions with an implantation energy of about 1 keV.

14. The method of claim 10, wherein the ion source is configured to implant charged ions with an implantation energy of about 30 keV.

15. The method of claim 10 wherein the predetermined dose is between 10¹³ ion/cm² to 5×10¹⁴ ions/cm².

16. The method of claim 10, wherein the predetermined dose is such that a concentration of implanted elements in the second IC layer is less than or equal to about 0.5 atomic % of a composition of the flowable dielectric material.

17. The method of claim 10, wherein the UV curing process further includes subjecting the second IC layer to UV radiation between about 150 nm to about 250 nm.

18. The method of claim 10, wherein a temperature experienced by second IC layer is equal to the substrate temperature, and the temperature is less than or equal to about 400° C.

19. The method of claim 10, wherein the first chemical backbone network strength has a first etch rate and the second chemical backbone strength has a second etch rate.

20. The method of claim 11, wherein the second etch rate is lower than the first etch rate.
